(19) United States
(12) Patent Application Publication
(10) Pub. No.: US 2015/0179533 A1
(43) Pub. Date: Jun. 25, 2015

(54) Semiconductor Manufacturing Apparatus and Method of Manufacturing Semiconductor Device

(71) Applicant: Kabushiki Kaisha Toshiba, Tokyo (JP)

(72) Inventors: Tomonori Aoyama, Yokkaichi (JP); Kyoichi Suguro, Yokohama (JP); Tatsunori Isogai, Yokkaichi (JP)

(21) Appl. No.: 14/482,265

(22) Filed: Sep. 10, 2014

(30) Foreign Application Priority Data
Dec. 24, 2013 (JP) 2013-265100

(51) Int. Cl. H01L 21/66; H01L 21/02; H05B 6/70; H05B 1/02; H05B 6/64; H01L 21/268; H01L 21/67

(52) U.S. Cl. CPC H01L 22/12; H01L 21/2686; H01L 21/02667; H01L 21/67115; H05B 1/0233; H05B 6/6452; H05B 6/707

(57) ABSTRACT

In one embodiment, a semiconductor manufacturing apparatus includes a support module configured to support a wafer which includes a substrate and a workpiece layer provided on the substrate and has a first face on a side of the workpiece layer and a second face on a side of the substrate, a chamber configured to contain the support module, and a microwave generator configured to generate a microwave. The apparatus further includes a waveguide provided on an upper face side or a lower face side of the chamber, and configured to irradiate the second face of the wafer with the microwave. The apparatus further includes a thermometer provided on the same side where the waveguide is provided selected from the upper face side and the lower face side of the chamber, and configured to measure a temperature on a side of the second face of the wafer.

### CROSS REFERENCE TO RELATED APPLICATION

This application is based upon and claims the benefit of priority from the prior Japanese Patent Application No. 2013-265100, filed on Dec. 24, 2013, the entire contents of which are incorporated herein by reference.

### FIELD

Embodiments described herein relate to a semiconductor manufacturing apparatus and a method of manufacturing a semiconductor device.

### BACKGROUND

A microwave is a kind of electromagnetic wave. A varying electric field of the microwave can cause a dipole to rotationally oscillate, and a varying magnetic field of the microwave can cause a current to flow in a conductor. Therefore, microwave annealing can generate a reaction such as activation of impurities or crystallization of an amorphous layer at a lower temperature, compared with infrared annealing and furnace annealing. However, when a wafer provided with a metal layer such as an electrode layer or an interconnect layer is irradiated with the microwave, sufficient power may not be supplied to a region where the reaction is desirably accelerated by the microwave (reaction acceleration target region). The reason is that part of the microwave is absorbed or reflected by the metal layer. Accordingly, the microwave annealing may result in insufficient activation of the impurities or insufficient crystallization of the amorphous layer. When the wafer provided with the metal layer is irradiated with the microwave, sufficient power can be supplied to the reaction acceleration target region by increasing microwave power or irradiation time. However, increasing the microwave power or irradiation time causes an increase in power consumption for the microwave annealing to increase manufacturing cost of a semiconductor device.

### BRIEF DESCRIPTION OF THE DRAWINGS

FIG. 1 is a cross-sectional view schematically illustrating a structure of a semiconductor manufacturing apparatus of a first embodiment;

FIG. 2 is a top view schematically illustrating a structure of a wafer transporting apparatus of the first embodiment;

FIGS. 3A and 3B are cross-sectional views comparing typical front-face irradiation and back-face irradiation of the first embodiment;

FIG. 4 is a cross-sectional view illustrating a structure of a semiconductor manufacturing apparatus of a second embodiment;

FIGS. 5A to 6C are cross-sectional views illustrating a method of manufacturing a semiconductor device of a third embodiment; and

FIGS. 7A to 9B are cross-sectional views illustrating a method of manufacturing a semiconductor device of a fourth embodiment.

### DETAILED DESCRIPTION

Embodiments will be explained with reference to the accompanying drawings.

In one embodiment, a semiconductor manufacturing apparatus includes a support module configured to support a wafer which includes a substrate and a workpiece layer provided on the substrate and has a first face on a side of the workpiece layer and a second face on a side of the substrate. The apparatus further includes a chamber configured to contain the support module. The apparatus further includes a microwave generator configured to generate a microwave. The apparatus further includes a waveguide provided on an upper face side or a lower face side of the chamber, and configured to irradiate the second face of the wafer with the microwave. The apparatus further includes a thermometer provided on the same side where the waveguide is provided selected from the upper face side and the lower face side of the chamber, and configured to measure a temperature on a side of the second face of the wafer.

### First Embodiment

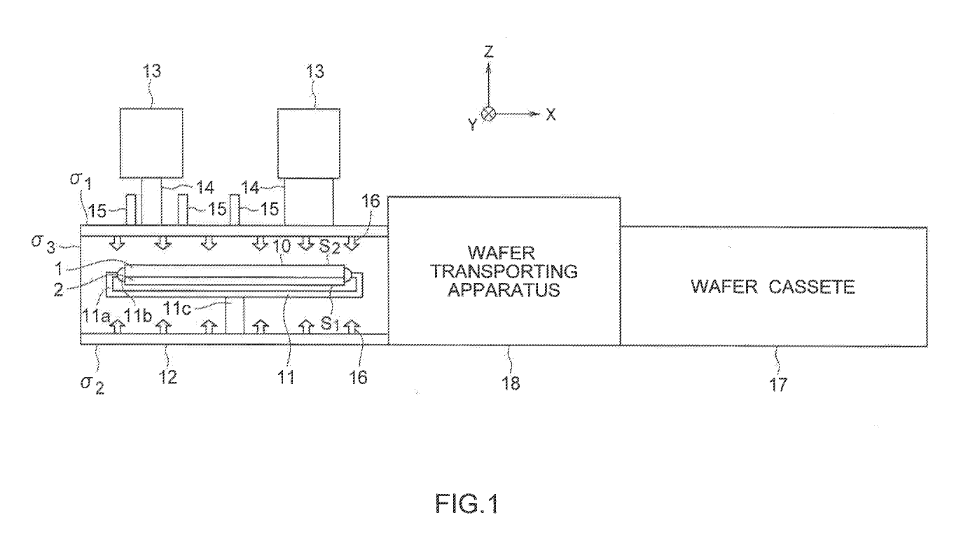

FIG. 1 is a cross-sectional view schematically illustrating a structure of a semiconductor manufacturing apparatus of a first embodiment.

The semiconductor manufacturing apparatus in FIG. 1 includes a support module 11, a chamber 12, one or more microwave generators 13, one or more waveguides 14, one or more thermometers 15, one or more gas nozzles 16, a wafer cassette 17, and a wafer transporting apparatus 18. The wafer cassette 17 and the wafer transporting apparatus 18 are examples of a container and a transporter, respectively. The semiconductor manufacturing apparatus in FIG. 1 is a microwave annealing apparatus for annealing a wafer 10 using microwaves.

[Support Module 11]

The support module 11 is configured to support the wafer 10, and includes a susceptor 11a, an edge grip 11b and a rotary shaft 11c. The susceptor 11a is formed of a transparent material such as quartz. The edge grip 11b is attached to an end portion of the susceptor 11a, and can support the wafer 10 by horizontally gripping an edge of the wafer 10. The rotary shaft 11c is attached to the back face of the susceptor 11a, and can rotate the wafer 10 in the horizontal plane of the wafer 10.

The wafer 10 in FIG. 1 includes a substrate 1, and one or more workpiece layers 2 formed on the substrate 1. An example of the substrate 1 is a semiconductor substrate such as a silicon substrate. Examples of the workpiece layers 2 are an inter layer dielectric, an isolation region, an electrode layer and an interconnect layer. The workpiece layers 2 in the present embodiment include one or more metal layers. Examples of the metal layers are an electrode layer including metal electrodes, and an interconnect layer including metal interconnects.

Reference symbol S₁ denotes a front face of the wafer 10, i.e., a face of the wafer 10 on a side of the workpiece layer 2. Reference symbol S₂ denotes a back face of the wafer 10, i.e., a face of the wafer 10 on a side of the substrate 1. The front face S₁ and the back face S₂ of the wafer 10 are examples of first and second faces. The wafer 10 of the present embodiment is supported by the support module 11 such that the front face S₁ faces downward and the back face S₂ faces upward.

FIG. 1 shows X and Y directions parallel to the front face S₁ and the back face S₂ of the wafer 10 and perpendicular to each other, and a Z direction perpendicular to the front face S₁ and the back face S₂ of the wafer 10. In the present specification, the +Z direction is regarded as an upward direction, and the −Z direction is regarded as a downward direction. For example, the positional relationship between the substrate 1 and the workpiece layer 2 is expressed that the workpiece layer 2 is located below the substrate 1.

[Chamber 12]

The chamber 12 contains the support module 11. In FIG. 1, the wafer 10 carried into the chamber 12 is supported by the support module 11. Reference symbols σ₁, σ₂ and σ₃ denote an upper face, a lower face and a side face of the chamber 12, respectively. The upper face σ₁ and the lower face σ₂ of the chamber 12 may be either parallel or non-parallel to each other. Shapes of the upper face σ₁ and the lower face σ₂ of the chamber 12 may be circular, elliptical or polygonal.

[Microwave Generators 13]

The microwave generators 13 generate microwaves. A frequency of the microwaves may be of any value. The microwave generators 13 of the present embodiment generate the microwaves having a frequency band of 2.40 to 24.25 GHz. From the viewpoint of the manufacturing cost and reliability of the microwave generators 13, the frequency of the microwaves is desirably, for example, a 2.45 GHz band, a 5.80 GHz band, or a 24.125 GHz band which is an industry-science-medical (ISM) band. An example of the microwave generators 13 is magnetrons.

[Waveguides 14]

The waveguides 14 connect the chamber 12 and the microwave generators 13, and emit the microwaves received from the microwave generators 13 into the chamber 12. The waveguides 14 of the present embodiment are disposed on an upper face at side of the chamber 12. Accordingly, the waveguides 14 of the present embodiment can irradiate the back face S₂ of the wafer 10 with the microwaves when the wafer 10 is supported such that the back face S₂ faces upward.

In order to supply uniform microwave power to the wafer 10, the semiconductor manufacturing apparatus of the present embodiment may irradiate the back face S₂ of the wafer 10 with the microwave while rotating the wafer 10 by the rotary shaft 11c.

[Thermometers 15]

Thermometers 15 measure a temperature of the wafer 10, and output the results of the temperature measurement. An example of the thermometers 15 is pyrometers. In this case, the thermometers 15 measure the temperature of the wafer 10 by measuring electromagnetic waves radiated from the wafer 10 through the window of the chamber 12. For example, the results of the temperature measurement by the thermometers 15 can also be used to control the operations of the rotary shaft 11c, the microwave generators 13 and the gas nozzles 16.

The thermometers 15 of the present embodiment are located on the same side as the waveguides 14 selected from the upper face σ₁ side and the lower face σ₂ side of the chamber 12. In other words, the thermometers 15 of the present embodiment are located on the upper face σ₁ side of the chamber 12. Accordingly, the thermometers 15 of the present embodiment can measure the temperature on the back face S₂ side of the wafer 10 when the wafer 10 is supported such that the back face S₂ faces upward. The reason of this is that it is difficult to precisely measure the temperature on the front face S₁ side of the wafer 10 since various patterns are formed on the front face S₁ side of the wafer 10. Details of this will be described later.

[Gas Nozzles 16]

The gas nozzles 16 are used to blow a coolant gas onto the wafer 10. The semiconductor manufacturing apparatus of the present embodiment can control the temperature of the wafer 10 by blowing the coolant gas onto the wafer 10. An example of the coolant gas is an inert gas.

The semiconductor manufacturing apparatus of the present embodiment includes a first gas nozzle 16 disposed on the upper face σ₁ side of the chamber 12 to blow the coolant gas onto the back face S₂ of the wafer 10, and a second gas nozzle 16 disposed on the lower face σ₂ side of the chamber 12 to blow the coolant gas onto the front face S₁ of the wafer 10. However, the semiconductor manufacturing apparatus of the present embodiment may include only either one of the first and second gas nozzles 16. In this case, since the back face S₂ of the wafer 10 is irradiated with the microwaves, the semiconductor manufacturing apparatus of the present embodiment desirably includes the first gas nozzle 16 capable of cooling the wafer 10 from the back face S₂ side of the wafer 10.

[Wafer Cassette 17]

The wafer cassette 17 is used to contain the wafer 10. The wafer cassette 17 of the present embodiment can contain the wafer 10 such that the front face S₁ faces upward and the back face S₂ faces downward.

[Wafer Transporting Apparatus 18]

The wafer transporting apparatus 18 carries the wafer 10 out of the wafer cassette 17 and into the chamber 12. The wafer 10 carried into the chamber 12 is supported by the support module 11.

The semiconductor manufacturing apparatus of the present embodiment irradiates the back face S₂ of the wafer 10 with the microwaves in a state that the back face S₂ of the wafer 10 faces upward. Accordingly, the support module 11 of the present embodiment supports the wafer 10 such that the back face S₂ faces upward. On the other hand, the wafer cassette 17 of the present embodiment contains the wafer 10 such that the front face S₁ faces upward.

Accordingly, the wafer transporting apparatus 18 of the present embodiment turns over the wafer 10 to change between the front face S₁ and the back face S₂, while carrying the wafer from the wafer cassette 17 to the chamber 12. This makes it possible to change the state of the wafer 10 from a state that the front face S₁ faces upward to a state that the back face S₂ faces upward.

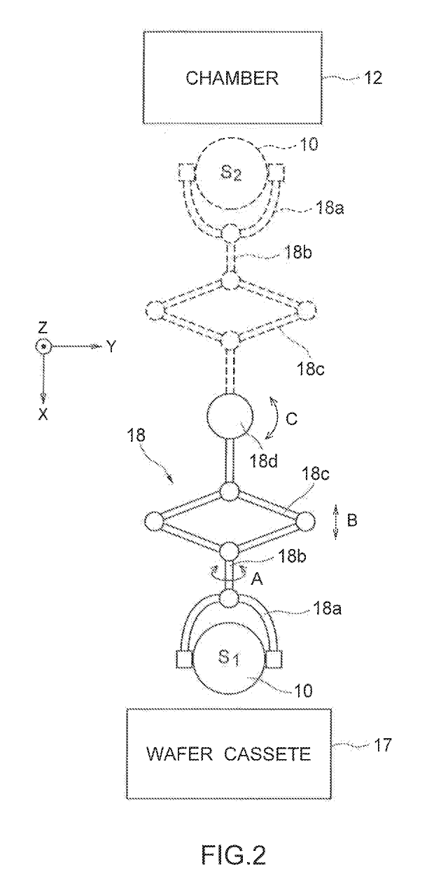

FIG. 2 is a top view schematically illustrating a structure of the wafer transporting apparatus 18 of the first embodiment.

As illustrated in FIG. 2, the wafer transporting apparatus 18 of the present embodiment includes a gripping module 18a, a first rotary module 18b, an extendable module 18c and a second rotary module 18d.

The gripping module 18a grips the wafer 10. The first rotary module 18b is rotatable as shown by an arrow A. The extendable module 18c is extensible and contractable as shown by an arrow B. The second rotary module 18d is rotatable as shown by an arrow C.

The wafer transporting apparatus 18 operates as described below. First, the wafer transporting apparatus 18 grips the wafer 10 in the wafer cassette 17 with the gripping module 18a. Next, the wafer transporting apparatus 18 carries the wafer 10 out of the wafer cassette 17 by contracting the extendable module 18c. The wafer transporting apparatus 18 then turns over the wafer 10 to change between the front face S₁ and the back face S₂ by rotating the first rotary module 18b. The wafer transporting apparatus 18 then moves the wafer 10 to the vicinity of the chamber 12 by rotating the second rotary module 18d. The wafer transporting apparatus 18 then carries the wafer 10 into the chamber 12 by extending the extendable module 18c.

It is acceptable to reverse the order of performing the operation to turn over the wafer 10 to change between the front face S₁ and the back face S₂ by the rotation of the first rotary module 18b and the operation to move the wafer 10 to the vicinity of the chamber 12 by the rotation of the second rotary module 18d.

The wafer transporting apparatus 18 of the present embodiment may have a structure different from the structure illustrated in FIG. 2, as long as the wafer transporting apparatus 18 can turn over the wafer 10 to change between the front face S₁ and the back face S₂.

(1) Details of Semiconductor Manufacturing Apparatus of First Embodiment

Referring to FIG. 1 again, details of the semiconductor manufacturing apparatus of the first embodiment will be described.

The semiconductor manufacturing apparatus of the present embodiment anneals the wafer 10 by irradiating the back face S₂ of the wafer 10 with the microwaves. The semiconductor manufacturing apparatus of the present embodiment adopts the following structures in order to irradiate the back face S₂ of the wafer 10 with the microwaves.

First, the support module 11 of the present embodiment supports the wafer 10 by gripping the wafer 10 with the edge grip 11b. Accordingly, the support module 11 of the present embodiment can support the wafer 10 almost without touching the front face S₁ and the back face S₂ of the wafer 10. Consequently, the present embodiment makes it possible to avoid causing the support module 11 to touch the front face S₁ of the wafer 10 to damage patterns on the front face S₁ of the wafer 10 when supporting the wafer 10 such that the back face S₂ faces upward.

Second, the waveguides 14 of the present embodiment are disposed on the upper face σ₁ side of the chamber 12. Consequently, the waveguides 14 of the present embodiment can irradiate the back face S₂ of the wafer 10 with the microwaves when the wafer 10 is supported such that the back face S₂ faces upward.

Third, the thermometers 15 of the present embodiment are disposed on the upper face σ₁ side of the chamber 12. Consequently, the thermometers 15 of the present embodiment can measure the temperature on the back face S₂ of the wafer 10 when the wafer 10 is supported such that the back face S₂ faces upward.

Here, a supplementary explanation will be made on the location of the thermometers 15. When the temperature at the time of the microwave annealing is measured, the temperature of the wafer 10 is desirably measured from the back face S₂ side of the wafer 10. The reason for this is that it is difficult to correct the thermometers 15 and precisely measure the temperature of the wafer 10 by the temperature measurement from the front face S₁ side of the wafer 10, since various patterns are formed on the front face S₁ side. Accordingly, the thermometers 15 are desirably located in positions where the thermometers 15 can measure the temperature of the back face S₂ of the wafer 10, as in the present embodiment.

The semiconductor manufacturing apparatus of the present embodiment includes the waveguides 14 disposed on the upper face σ₁ side of the chamber 12, whereas the apparatus includes no waveguide 14 disposed on the lower face σ₂ side of the chamber 12. Accordingly, the semiconductor manufacturing apparatus of the present embodiment includes the waveguides 14 for irradiating the back face S₂ of the wafer 10 with the microwaves, whereas the apparatus includes no waveguide 14 for irradiating the front face S₁ of the wafer 10 with the microwaves.

Similarly, the semiconductor manufacturing apparatus of the present embodiment includes the thermometers 15 disposed on the upper face σ₁ side of the chamber 12, whereas the apparatus includes no thermometer 15 disposed on the lower face σ₂ side of the chamber 12. Accordingly, the semiconductor manufacturing apparatus of the present embodiment includes the thermometers 15 for measuring the temperature on the back face S₂ side of the wafer 10, whereas the apparatus includes no thermometer 15 for measuring the temperature on the front face S₁ side of the wafer 10.

(2) Comparison Between Front-Face Irradiation and Back-Face Irradiation

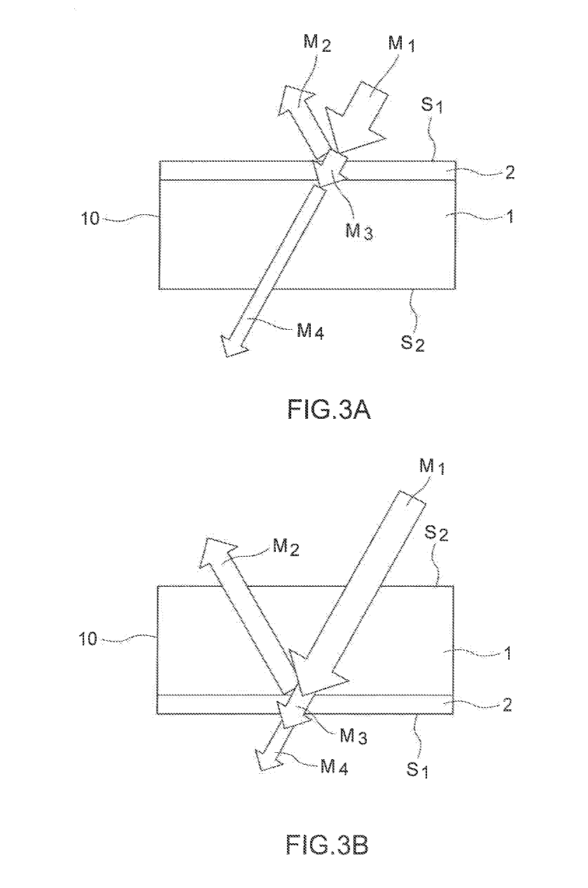

FIGS. 3A and 3B are cross-sectional views comparing typical front-face irradiation and back-face irradiation of the first embodiment.

In FIGS. 3A and 3B, reference symbol M₁ denotes a microwave incident onto the workpiece layers 2. Reference symbol M₂ denotes a microwave reflected by the workpiece layers 2. Reference symbol M₃ denotes a microwave transmitting through the workpiece layers 2. Reference symbol M₄ denotes a microwave having transmitted through the workpiece layers 2. The thicknesses of reference symbols M₁ to M₄ schematically represent the magnitudes of microwave power.

FIG. 3A illustrates the typical front-face irradiation used to irradiate the front face S₁ of the wafer 10 with the microwaves. In this case, most of the microwave M₁ incident onto the workpiece layers 2 is absorbed or reflected by the metal layer in the workpiece layers 2. For this reason, a sufficient amount of microwave does not reach the substrate 1. Specifically, only the microwave M₄ reaches the substrate 1.

FIG. 3B illustrates the back-face irradiation of the first embodiment for irradiating the back face S₂ of the wafer 10 with the microwaves. In this case, the microwave M₁ reaches the substrate 1 before entering the workpiece layers 2. For this reason, the microwave M₁ having sufficient power can reach the reaction acceleration target region in the substrate 1 in the present embodiment. Consequently, the present embodiment makes it possible to sufficiently accelerate the reactions by irradiating the reaction acceleration target region in the substrate 1 with a low-power microwave for short time. In addition, the present embodiment makes it possible to supply power to the substrate 1 by using both the microwave M₁ as an incident wave and the microwave M₂ as a reflected wave. Accordingly, it is possible in the present embodiment to more efficiently accelerate the reactions in the reaction acceleration target region in the substrate 1.

The workpiece layers 2 in FIGS. 3A and 3B are Joule-heated by a varying magnetic field of the microwave M₃. The difference between the energy of the microwave M₃ and the energy of the microwave M₄ corresponds to the amount of heat contributing to the heating of the workpiece layers 2.

The microwave generators 13 of the present embodiment may generate electromagnetic waves having wavelengths of microwaves and millimeter waves.

As described above, both the waveguides 14 and the thermometers 15 of the present embodiment are disposed on the upper face σ₁ side of the chamber 12. Therefore, the present embodiment makes it possible to provide the semiconductor manufacturing apparatus that irradiates the back face S₂ of the wafer 10 with the microwaves to supply sufficient power to the wafer 10 and precisely measures the temperature on the back face S₂ side of the wafer 10 at this time. Consequently, when the reactions in the wafer 10 are to be accelerated by the microwaves, the present embodiment makes it possible to efficiently supply power to the reaction acceleration target region in the wafer 10 by irradiating the back face S₂ of the wafer 10 with the microwaves by such a semiconductor manufacturing apparatus. As a result, the present embodiment makes it possible to decrease power consumption for the microwave annealing to reduce the manufacturing cost of a semiconductor device.

### Second Embodiment

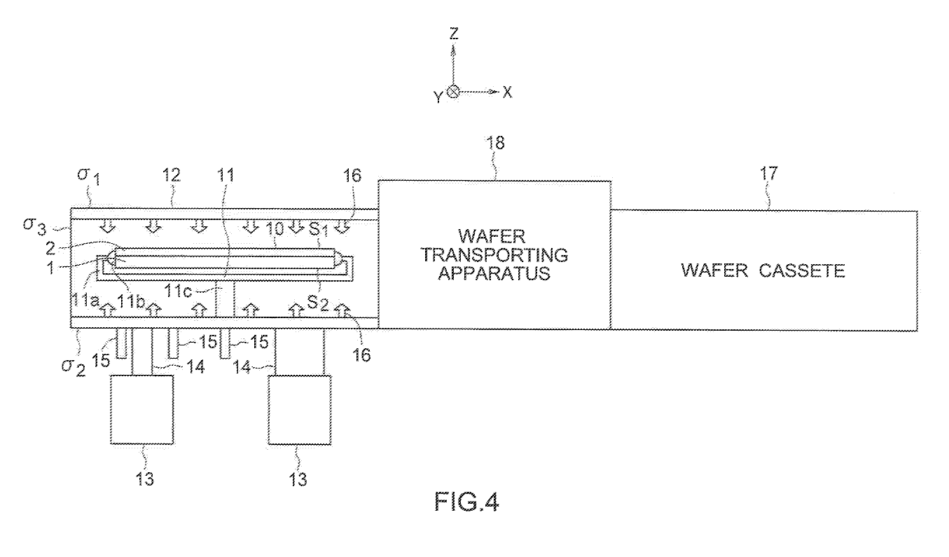

FIG. 4 is a cross-sectional view illustrating a structure of a semiconductor manufacturing apparatus of a second embodiment.

The wafer 10 of the present embodiment is supported by the support module 11 such that the front face S₁ faces upward and the back face S₂ faces downward. In addition, both the waveguides 14 and the thermometers 15 of the present embodiment are disposed on the lower face σ₂ side of the chamber 12. Consequently, the waveguides 14 of the present embodiment can irradiate the back face S₂ of the wafer 10 with the microwaves, and the thermometers 15 of the present embodiment can measure the temperature on the back face S₂ side of the wafer 10.

The semiconductor manufacturing apparatus of the present embodiment includes the first gas nozzle 16 disposed on the upper face σ₁ side of the chamber 12 to blow the coolant gas onto the front face S₁ of the wafer 10, and the second gas nozzle 16 disposed on the lower face σ₂ side of the chamber 12 to blow the coolant gas onto the back face S₂ of the wafer 10. However, the semiconductor manufacturing apparatus of the present embodiment may include only either one of the first and second gas nozzles 16. In this case, since the semiconductor manufacturing apparatus irradiates the back face S₂ of the wafer 10 with the microwaves, the semiconductor manufacturing apparatus of the present embodiment desirably includes the second gas nozzle 16 capable of cooling the wafer 10 from the back face S₂ side.

The semiconductor manufacturing apparatus of the present embodiment includes the waveguides 14 disposed on the lower face σ₂ side of the chamber 12, whereas the apparatus includes no waveguide 14 disposed on the upper face σ₁ side of the chamber 12. Accordingly, the semiconductor manufacturing apparatus of the present embodiment includes the waveguides 14 for irradiating the back face S₂ of the wafer 10 with the microwaves, whereas the apparatus includes no waveguide 14 for irradiating the front face S₁ of the wafer 10 with the microwaves.

Similarly, the semiconductor manufacturing apparatus of the present embodiment includes the thermometers 15 disposed on the lower face σ₂ side of the chamber 12, whereas the apparatus includes no thermometer 15 disposed on the upper face σ₁ side of the chamber 12. Accordingly, the semiconductor manufacturing apparatus of the present embodiment includes the thermometers 15 for measuring the temperature on the back face S₂ side of the wafer 10, whereas the apparatus includes no thermometer 15 for measuring the temperature on the front face S₁ side of the wafer 10.

As described above, both the waveguides 14 and the thermometers 15 of the present embodiment are disposed on the lower face σ₂ side of the chamber 12. Therefore, the present embodiment makes it possible to provide the semiconductor manufacturing apparatus that irradiates the back face S₂ of the wafer 10 with the microwaves to supply sufficient power to the wafer 10 and precisely measures the temperature on the back face S₂ side of the wafer 10 at this time, similarly to the first embodiment. Consequently, when the reactions in the wafer 10 are to be accelerated by the microwaves, the present embodiment makes it possible to efficiently supply power to the reaction acceleration target region in the wafer 10 by irradiating the back face S₂ of the wafer 10 with the microwaves by such a semiconductor manufacturing apparatus.

The support module 11 of the present embodiment supports the wafer 10 such that the front face S₁ faces upward, and the wafer cassette 17 of the present embodiment contains the wafer 10 such that the front face S₁ faces upward. Accordingly, the wafer transporting apparatus 18 of the present embodiment need not have a function of turning over the wafer 10 to change between the front face S₁ and the back face S₂. In addition, the support module 11 of the present embodiment may support the wafer 10 such that the support module 11 contacts the back face S₂ of the wafer 10. For example, the support module 11 of the present embodiment may support the wafer 10 with pins or a support plane that contact(s) the back face S₂ of the wafer 10, instead of the edge grip 11b that contacts an edge of the wafer 10.

On the other hand, the semiconductor manufacturing apparatus of the first embodiment has an advantage that the waveguides 14 and the thermometers 15 can be disposed on the upper face σ₁ side of the chamber 12 where only a small number of devices are disposed and there is enough space.

### Third Embodiment

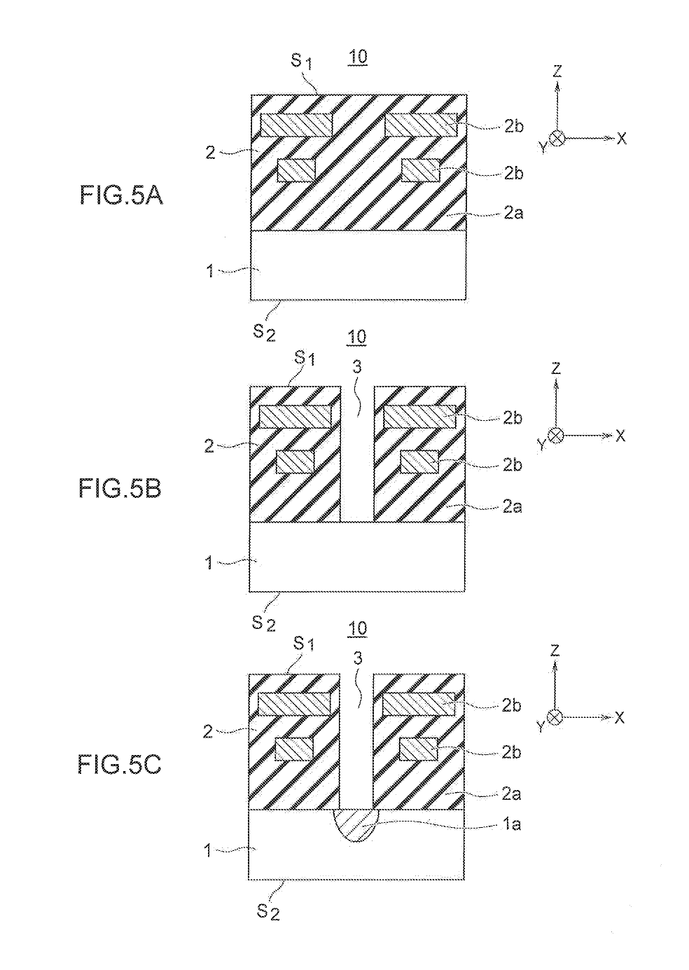

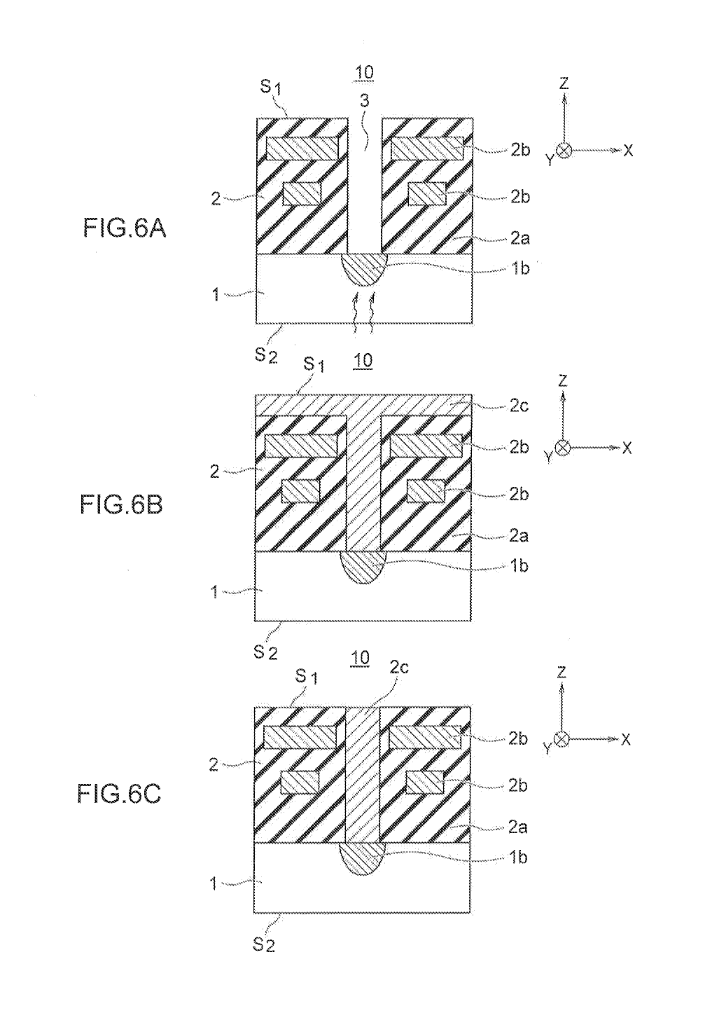

FIGS. 5A to 6C are cross-sectional views illustrating a method of manufacturing a semiconductor device of a third embodiment.

As illustrated in FIG. 5A, the one or more workpiece layers 2 are formed on the substrate 1. The workpiece layers 2 in FIG. 5A include one or more inter layer dielectrics 2a formed on the substrate 1, and one or more metal layers 2b formed on the substrate 1 so as to be covered with the inter layer dielectrics 2a. Reference symbol S₁ denotes the front face of the wafer 10, i.e., a face of the wafer 10 on the side of the workpiece layers 2. Reference symbol S₂ denotes the back face of the wafer 10, i.e., a face of the wafer 10 on the side of substrate 1.

As illustrated in FIG. 5B, a contact hole 3 is formed in the inter layer dielectrics 2a by lithography and reactive ion etching. The contact hole 3 is formed such that the bottom face of the contact hole 3 reaches the substrate 1.

As illustrated in FIG. 5C, n-type impurities or p-type impurities are introduced into the substrate 1 at the bottom face of the contact hole 3 by ion implantation or plasma doping. As a result, an amorphous layer 1a is formed in the substrate 1. The dose amount of the impurities is set to, for example, 1.0×10¹⁵ cm⁻² or larger.

As illustrated in FIG. 6A, the back face S₂ of the wafer 10 is irradiated with the microwaves by using the semiconductor manufacturing apparatus of the first or second embodiment to heat the amorphous layer 1a. Consequently, the amorphous layer 1a is crystallized into a single crystal, and the impurities in the amorphous layer 1a are activated. As a result, a diffusion layer 1b is formed from the amorphous layer 1a.

As illustrated in FIG. 6B, a metal layer 2c is formed on the entire surface of the substrate 1 to fill the metal layer 2c in the contact hole 3. The metal layer 2c is, for example, a stack film including a titanium (Ti) layer, a titanium nitride (TiN) layer and a tungsten (W) layer.

As illustrated in FIG. 6C, a surface of the metal layer 2c is planarized by chemical mechanical polishing (CMP) to remove portions of the metal layer 2c outside the contact hole 3. As a result, a contact plug including the metal layer 2c and electrically connected to the diffusion layer 1b is formed in the contact hole 3.

In the method of manufacturing the semiconductor device of the present embodiment, the back-face irradiation illustrated in FIG. 6A was actually performed under the following conditions. The total power of the microwaves from the waveguides 14 was set to 3 kW, and the irradiation time of the microwaves was set to 40 seconds. The flow rate of the coolant gas from each gas nozzle 16 was set such that the temperature of the wafer 10 to be measured by the thermometers 15 was fixed at 600° C. A nitrogen (N₂) gas was used as the coolant gas. As a result, the flow rate of the coolant gas from each gas nozzle 16 was set to 40 slm.

On the other hand, in the method of manufacturing the semiconductor device of the present embodiment, the back-face irradiation illustrated in FIG. 6A was changed to the front-face irradiation for comparison, and the front-face irradiation was performed under the following conditions. The total power of the microwaves from the waveguides 14 was set to 3 kW, and the irradiation time of the microwaves was set to 40 seconds. The flow rate of the coolant gas from each gas nozzle 16 was set such that the temperature of the wafer 10 to be measured by the thermometers 15 was fixed at 600° C. The N₂ gas was used as the coolant gas. As a result, the flow rate of the coolant gas from each gas nozzle 16 was set to 20 slm.

As described above, the flow rate of the coolant gas at the time of the back-face irradiation was set to larger than the flow rate of the coolant gas at the time of the front-face irradiation, when the temperature of the wafer 10 was fixed at 600° C. This means that the efficiency of heating the wafer 10 by the back-face irradiation was higher than the efficiency of heating the wafer 10 by the front-face irradiation. In other words, since the wafer 10 absorbed a larger amount of power due to the back-face irradiation, a larger amount of coolant gas was used to sufficiently cool the wafer 10 at the time of the back-face irradiation.

The power of the microwaves and the flow rate of the coolant gas adopted in the present embodiment depend on a wafer size and a chamber structure, and therefore may be changed as appropriate.

The cross-section of the wafer 10 immediately after the front-face irradiation and the back-face irradiation were observed. The observation of the wafer 10 immediately after the front-face irradiation proved that the amorphous layer 1a remained partially, and therefore the impurity activation was insufficient. On the other hand, the observation of the wafer 10 immediately after the back-face irradiation proved that the amorphous layer 1a completely turned into a single crystal.

As described above, the present embodiment makes it possible, by efficiently supplying power to the reaction acceleration target region by the back-face irradiation of the microwaves, to accelerate the reactions in the reaction acceleration target region in the wafer 10.

### Fourth Embodiment

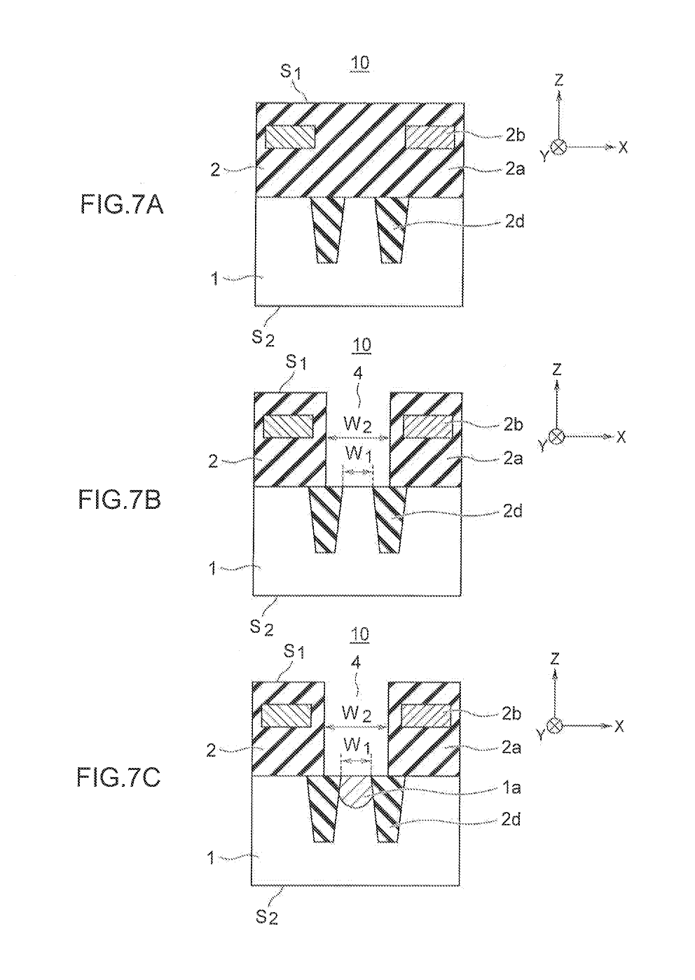

FIGS. 7A to 9B are cross-sectional views illustrating a method of manufacturing a semiconductor device of a fourth embodiment.

As illustrated in FIG. 7A, the one or more workpiece layers 2 are formed on the substrate 1. The workpiece layers 2 illustrated in FIG. 7A include the one or more inter layer dielectrics 2a formed on the substrate 1, the one or more metal layers 2b formed on the substrate 1 so as to be covered with the inter layer dielectrics 2a, and isolation regions 2d formed on the substrate 1 so as to be covered with the inter layer dielectrics 2a. The isolation regions 2d are formed by forming isolation trenches in the front face of the substrate 1 and filling an insulating layer in the isolation trenches.

As illustrated in FIG. 7B, a trench 4 is formed in the inter layer dielectrics 2a by lithography and reactive ion etching. The trench 4 is formed such that the bottom face of the trench 4 reaches the substrate 1. Reference symbol W₁ denotes the distance between the isolation regions 2d adjacent to each other, and reference symbol W₂ denotes the width of the trench 4. The distance W₁ of the present embodiment is set to 20 nm or shorter, and the width W₂ of the present embodiment is set to larger than the distance W₁.

As illustrated in FIG. 7C, the n-type impurities or the p-type impurities are introduced into the substrate 1 at the bottom face of the trench 4 by ion implantation or plasma doping. As a result, the amorphous layer 1a is formed between the isolation regions 2d in the substrate 1. The dose amount of the impurities is set to, for example, 1.0×10¹⁵ cm⁻² or larger.

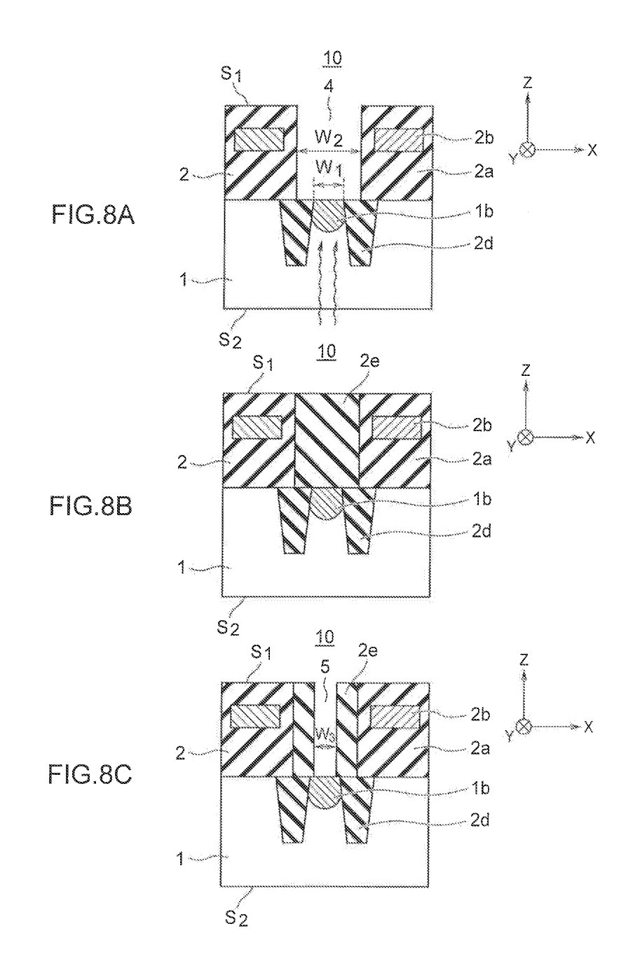

As illustrated in FIG. 8A, the back face S₂ of the wafer 10 is irradiated with the microwaves by using the semiconductor manufacturing apparatus of the first or second embodiment. Consequently, the amorphous layer 1a is crystallized into a single crystal, and the impurities in the amorphous layer 1a are activated. As a result, the diffusion layer 1b is formed from the amorphous layer 1a.

As illustrated in FIG. 8B, an inter layer dielectric 2e is formed on the entire surface of the substrate 1, and a surface of the inter layer dielectric 2e is planarized by CMP. As a result, the inter layer dielectric 2e is filled in the trench 4.

As illustrated in FIG. 8C, a contact hole 5 is formed in the inter layer dielectric 2e by lithography and reactive ion etching. The contact hole 5 is formed such that the bottom face of the contact hole 5 reaches the diffusion layer 1b. Reference symbol W₃ denotes the width of the contact hole 5. The width W₃ of the present embodiment may be either smaller or larger than the distance W₁.

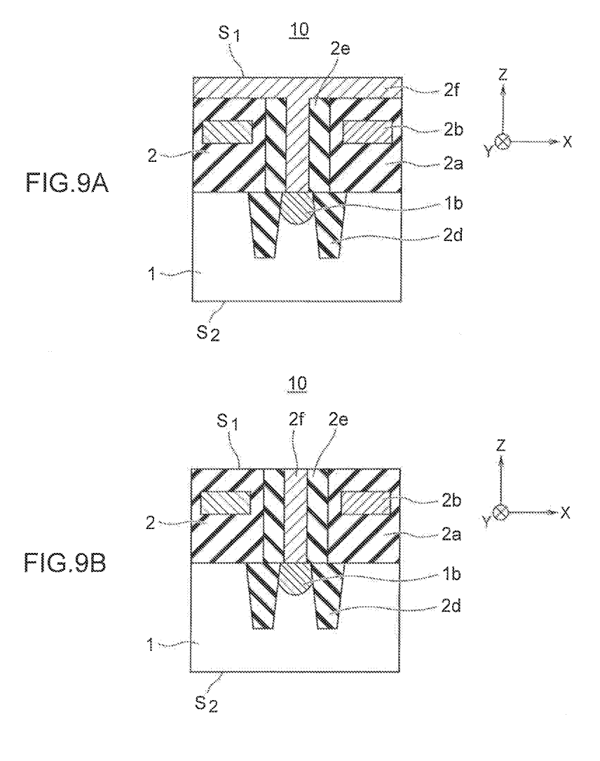

As illustrated in FIG. 9A, a metal layer 2f is formed on the entire surface of the substrate 1 to fill the metal layer 2f in the contact hole 5. The metal layer 2f is, for example, a stack film including a Ti layer, a TiN layer and a W layer.

As illustrated in FIG. 9B, a surface of the metal layer 2f is planarized by CMP to remove portions of the metal layer 2f outside the contact hole 5. As a result, a contact plug including the metal layer 2f and electrically connected to the diffusion layer 1b is formed in the contact hole 5.

In the method of manufacturing the semiconductor device of the present embodiment, the back-face irradiation illustrated in FIG. 8A was actually performed under the following conditions. The total power of the microwaves from the waveguides 14 was set to 5 kW, and the irradiation time of the microwaves was set to 180 seconds. The flow rate of the coolant gas from each gas nozzle 16 was set such that the temperature of the wafer 10 to be measured by the thermometers 15 was fixed at 700° C. A N₂ gas was used as the coolant gas. As a result, the flow rate of the coolant gas from each gas nozzle 16 was set to 60 slm.

On the other hand, in the method of manufacturing the semiconductor device of the present embodiment, the back-face irradiation illustrated in FIG. 8A was changed to the front-face irradiation for comparison, and the front-face irradiation was performed under the following conditions. The total power of the microwaves from the waveguides 14 was set to 5 kW, and the irradiation time of the microwaves was set to 180 seconds. The flow rate of the coolant gas from each gas nozzle 16 was set such that the temperature of the wafer 10 to be measured by the thermometers 15 was fixed at 700° C. An N₂ gas was used as the coolant gas. As a result, the flow rate of the coolant gas from each gas nozzle 16 was set to 20 slm.

As described above, the flow rate of the coolant gas at the time of the back-face irradiation was set to larger than the flow rate of the coolant gas at the time of the front-face irradiation, when the temperature of the wafer 10 was fixed at 700° C. This means that the efficiency of heating the wafer 10 by the back-face irradiation was higher than the efficiency of heating the wafer 10 by the front-face irradiation. In other words, since the wafer 10 absorbed a larger amount of power due to the back-face irradiation, a larger amount of coolant gas was used to sufficiently cool the wafer 10 at the time of the back-face irradiation.

The cross-section of the wafer 10 immediately after the front-face irradiation and the back-face irradiation were observed. The observation of the wafer 10 immediately after the front-face irradiation proved that the crystallization of the amorphous layer 1a hardly occurred. A possible reason for this is that the amorphous layer 1a is formed between the isolation regions 2d where the distance W₁ is as short as no more than 20 nm, which makes the growth rate of the amorphous layer 1a in a solid phase extremely low and requires a large amount of power compared with a case where the distance W₁ is long, but sufficient microwave power is not supplied to the amorphous layer 1a in the case of the front-face irradiation. On the other hand, the observation of the wafer 10 immediately after the back-face irradiation proved that the amorphous layer 1a completely turned into a single crystal. A possible reason for this is that even if the distance W₁ is short, sufficient microwave power is supplied to the amorphous layer 1a in the case of the back-face irradiation.

As described above, the present embodiment makes it possible, by efficiently supplying power to the reaction acceleration target region by the back-face irradiation of the microwaves, to accelerate the reactions in the reaction acceleration target region in the wafer 10.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A semiconductor manufacturing apparatus comprising:
a support module configured to support a wafer which includes a substrate and a workpiece layer provided on the substrate and has a first face on a side of the workpiece layer and a second face on a side of the substrate;
a chamber configured to contain the support module;
a microwave generator configured to generate a microwave;
a waveguide provided on an upper face side or a lower face side of the chamber, and configured to irradiate the second face of the wafer with the microwave; and
a thermometer provided on the same side where the waveguide is provided selected from the upper face side and the lower face side of the chamber, and configured to measure a temperature on a side of the second face of the wafer.

2. The apparatus of claim 1, wherein the waveguide and the thermometer are provided on the upper face side of the chamber.

3. The apparatus of claim 2, wherein the support module supports the wafer such that the second face of the wafer faces upward.

4. The apparatus of claim 2, wherein the support module supports the wafer by gripping an edge of the wafer.

5. The apparatus of claim 2, further comprising one or more gas nozzles provided on the upper face side of the chamber, and configured to supply a coolant gas to the wafer.

6. The apparatus of claim 2, further comprising:
a container configured to contain the wafer; and
a transporter configured to carry the wafer out of the container, turn over the wafer to change between the first face and the second face, and carry the wafer into the chamber.

7. The apparatus of claim 6, wherein the transporter includes:
a gripping module configured to grip the wafer; and
a rotary module configured to rotate the wafer gripped by the gripping module to turn over the wafer to change between the first face and the second face.

8. The apparatus of claim 1, wherein the waveguide and the thermometer are provided on the lower face side of the chamber.

9. The apparatus of claim 8, wherein the support module supports the wafer such that the second face of the wafer faces downward.

10. The apparatus of claim 8, wherein the support module supports the wafer such that the support module contacts the second face of the wafer.

11. The apparatus of claim 8, further comprising one or more gas nozzles provided on the lower face side of the chamber, and configured to supply a coolant gas to the wafer.

12. The apparatus of claim 1, comprising no waveguide configured to irradiate the first face of the wafer with the microwave.

13. A method of manufacturing a semiconductor device, comprising:
carrying a wafer into a chamber, the wafer including a substrate and a workpiece layer provided on the substrate and having a first face on a side of the workpiece layer and a second face on a side of the substrate;
supporting the wafer by a support module in the chamber;
generating a microwave from a microwave generator;
irradiating the second face of the wafer with the microwave by a waveguide provided on an upper face side or a lower face side of the chamber; and
measuring a temperature on a side of the second face of the wafer by a thermometer provided on the same side where the waveguide is provided selected from the upper face side and the lower face side of the chamber.

14. The method of claim 13, wherein the waveguide and the thermometer are provided on the upper face side of the chamber.

15. The method of claim 14, wherein the support module supports the wafer such that the second face of the wafer faces upward.

16. The method of claim 14, further comprising carrying the wafer out of a container, turning over the wafer to change between the first face and the second face, and carrying the wafer into the chamber.

17. The method of claim 13, wherein the waveguide and the thermometer are provided on the lower face side of the chamber.

18. The method of claim 17, wherein the support module supports the wafer such that the second face of the wafer faces downward.

19. The method of claim 13, wherein the wafer includes isolation regions provided on the substrate, and an amorphous layer provided between the isolation regions in the substrate,
the method further comprising irradiating the second face of the wafer with the microwave to crystallize the amorphous layer.

20. The method of claim 19, wherein a distance between the isolation regions is 20 nm or less.
